(19) United States
(12) Patent Application Publication
(10) Pub. No.: US 2025/0306111 A1
(43) Pub. Date: Oct. 2, 2025

(54) ESTIMATION OF AUXILIARY LOADS IN HYBRID OR BATTERY ELECTRIC VEHICLES FOR FAILURE DETECTION

(71) Applicant: Garrett Transportation I Inc., Torrance, CA (US)

(72) Inventors: Martin Herceg, Bratislava (SK); Bohumil Hnilicka, Troubelice (CZ); David Vosahlik, Prague (CZ)

(73) Assignee: Garrett Transportation I Inc., Torrance, CA (US)

(21) Appl. No.: 18/618,850

(22) Filed: Mar. 27, 2024

(51) Int. Cl. G01R 31/367; G01R 31/36; G01R 31/3842

(52) U.S. Cl. CPC G01R 31/367; G01R 31/3648; G01R 31/3842

(57) ABSTRACT

Methods and systems for quantifying and monitoring auxiliary power usage and losses in an electrified vehicle. The auxiliary power is treated as an unknown disturbance in a Kalman filter, which compares power generated from the battery pack to power of the motor generator unit (MGU). The auxiliary power is considered as a sum of all auxiliary power usage and power losses in the vehicle, including in the MGU. The calculated auxiliary power from the Kalman filter is compared to a threshold to generate an alert, or to aid in range estimation, or to update battery state of charge estimates.

### BACKGROUND

In battery and/or hybrid electric vehicles, a high power battery is present. Most of the energy from the high power battery is used for propulsion, and the remainder of the energy to auxiliary device usage (cabin environmental controls, for example), while some is lost or wasted due to system inefficiencies, errors, and/or failures. A coulomb counter or other current monitoring device is typically used to track current leaving the battery. However, there is little analysis of auxiliary power usage and power losses in most systems. New and alternative systems and methods for estimating auxiliary loads and/or losses, and ways of using such estimates, are desired.

### Overview

The present inventors have recognized that a problem to be solved is the need for new and/or alternative systems and methods for estimating auxiliary loads in hybrid or battery electric vehicles. Doing so may allow for failure identification, as well as enhancing various models of battery state, range estimates, etc. In the case of electronic failures, for example a short circuit causing power losses, battery energy may be excessively drained causing depletion, and reducing range.

A first illustrative and non-limiting example takes the form of a method of estimating power losses in a vehicle having a motor-generator-unit (MGU) used by the vehicle to provide motive power, the method comprising: calculating or measuring torque of the MGU: calculating or measuring speed of the MGU; using the MGU torque and MGU speed to determine MGU power; measuring current output of a battery pack of the vehicle; measuring voltage of the battery pack of the vehicle; using the measured current and measured voltage to determine battery pack output power; applying the MGU power and battery pack power as inputs to a Kalman filter; treating the power losses as an unknown disturbance in the Kalman filter; and obtaining an estimate of the power losses from the Kalman filter.

Additionally or alternatively, the estimate of power losses includes power used by auxiliary systems of the vehicle as well as power losses in the MGU. Additionally or alternatively, the method also includes estimating or measuring known auxiliary power uses in the vehicle, and applying the known auxiliary power uses as an input to the Kalman filter, wherein the estimate of power losses from the Kalman filter omits the known auxiliary power uses. Additionally or alternatively, the speed of the MGU is measured by a speed sensor. Additionally or alternatively, the torque of the MGU is calculated from an MGU power request.

Additionally or alternatively, the method also includes comparing the estimated power losses to a threshold, finding that the estimated power losses exceed the threshold, and generating an alert in response to the estimated power losses exceeding the threshold. Additionally or alternatively, the method also includes correcting a range estimate for the vehicle using the estimated power losses, and reporting the corrected range estimate to a driver of the vehicle. Additionally or alternatively, the Kalman filter is an Unscented Kalman Filter, an Extended Kalman Filter, or an Iterated Extended Kalman Filter. Additionally or alternatively, the vehicle is a purely electric vehicle. Additionally or alternatively, the vehicle is a hybrid vehicle having, in addition to the MGU, a fuel cell or a combustion engine for providing motive power.

Another illustrative, non-limiting example takes the form of a configurable controller for a vehicle having a motor-generator-unit (MGU) used by the vehicle to provide motive power, the configurable controller programmed to perform a method of estimating power losses in the vehicle by: calculating or measuring torque of the MGU: calculating or measuring speed of the MGU; using the MGU torque and MGU speed to determine MGU power; measuring current output of a battery pack of the vehicle; measuring voltage of the battery pack of the vehicle; using the measured current and measured voltage to determine battery pack output power; applying the MGU power and battery pack power as inputs to a Kalman filter; treating the power losses as an unknown disturbance in the Kalman filter; and obtaining an estimate of the power losses from the Kalman filter.

Additionally or alternatively, the estimate of power losses includes power used by auxiliary systems of the vehicle as well as power losses in the MGU. Additionally or alternatively, the configurable controller is further programmed for estimating or measuring known auxiliary power uses in the vehicle, and applying the known auxiliary power uses as an input to the Kalman filter, wherein the estimate of power losses from the Kalman filter omits the known auxiliary power uses. Additionally or alternatively, the speed of the MGU is measured by a speed sensor. Additionally or alternatively, the torque of the MGU is calculated from an MGU power request.

Additionally or alternatively, the configurable controller is programmed for comparing the estimated power losses to a threshold, finding that the estimated power losses exceed the threshold, and generating an alert in response to the estimated power losses exceeding the threshold. Additionally or alternatively, the configurable controller is further programmed for correcting a range estimate for the vehicle using the estimated power losses, and reporting the corrected range estimate to a driver of the vehicle. Additionally or alternatively, the Kalman filter is an Unscented Kalman Filter, an Extended Kalman Filter, or an Iterated Extended Kalman Filter.

Additionally or alternatively, the configurable controller is part of a vehicle having a motor-generator unit, wherein the vehicle is a purely electric vehicle. Additionally or alternatively, the configurable controller is part of a vehicle having a motor-generator unit, and a fuel cell or a combustion engine for providing motive power.

Still further examples take the form of methods of operating an electrical architecture as in any of the preceding examples, and controller configured or adapted for performing such methods in associated with an electrical architecture as in any of the preceding examples.

This overview is intended to provide an introduction to the subject matter of the present patent application. It is not intended to provide an exclusive or exhaustive explanation. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a block diagram of a vehicle having an electric drive motor;

FIG. 2 illustrates power sources and power uses in an electric vehicle;

FIG. 3 illustrates an analysis of auxiliary loads;

FIG. 4 illustrates an auxiliary power estimation; and

FIG. 5 shows in block form generation and use of an auxiliary power estimate.

### DETAILED DESCRIPTION

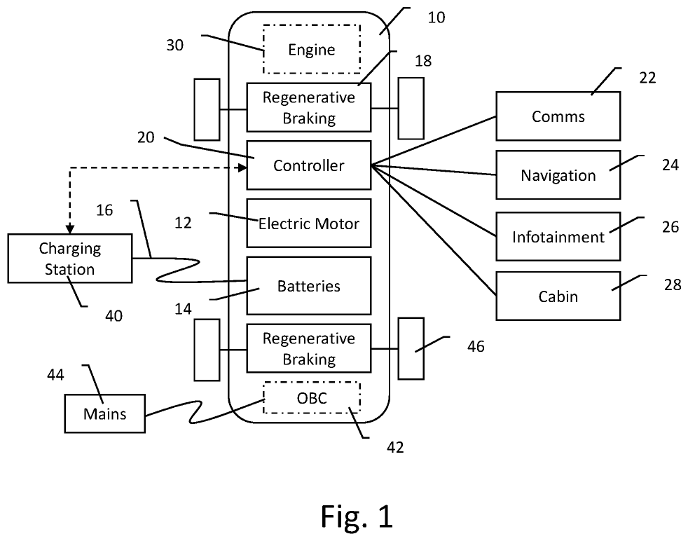

FIG. 1 is a block diagram of a vehicle having an electric drive motor. The skilled person will recognize that, for brevity, the following discussion may not necessarily describe every feature that would be present in the vehicle 10. The vehicle 10 is characterized by an electric motor 12 (or plural electric motors 12) which take the form of traction motor(s) that provide motive power/force to the vehicle 10, powered by batteries 14. The batteries 14 may have any suitable chemistry. Batteries 14 may be associated with various secondary features, such as warming and/or cooling apparatuses to maintain suitable temperatures therein. Regenerative braking 18 may be provided, and serves to at least partly recharge the batteries 14 under suitable braking conditions. The combination of electric motor(s) 12 and regenerative braking 18 may be understood as a motor generator unit (MGU) combining a traction motor and a generator in one “electric” motor which can either consume current from batteries 14 or generate current to charge the batteries 14 under different conditions.

A controller 20 is coupled to each of these blocks, and may further be linked to control blocks for communications 22, navigation 24, infotainment 26, and cabin 28. The controller 20 is configured for sending and receiving information as well as to provide and/or control power used by, for example, an air conditioning unit used for cooling the cabin 28, or other environmental controls for the cabin 28. The communications 22 may include any of satellite, cellular, Bluetooth, broadband, WiFi, and/or various other wireless communications circuits, antennae, receivers, transceivers, transmitters, etc., as desired. The communications 22 may allow the controller 20 to send and receive data relative to one or more internet, dedicated, and/or cloud-based data receiving and/or processing centers, such as a fleet monitor. The communications 22 may be used to upload and/or download data of various types.

The controller 20, as well as other control blocks described in FIG. 1 and other figures below may take many forms, including, for example, a microcontroller or microprocessor, coupled to a memory storing readable instructions for performing methods as described herein, as well as providing configuration of the controller for the various examples that follow. The controller may include one more application-specific integrated circuits (ASIC) to provide additional or specialized functionality, such as, without limitation a signal processing ASIC that can filter received signals from one or more sensors using digital filtering techniques. Logic circuitry, state machines, and discrete or integrated circuit components may be included as well. Such devices, including engine control units (ECUs) are common in the automotive/vehicle industry, but the skilled person will recognize many different hardware implementations are available for a controller. The controller 20 may include, be part of, or communicate with an advanced control framework as disclosed in U.S. patent application Ser. No. 17/241,668, filed Apr. 27, 2021 and titled ADVANCED CONTROL FRAMEWORK FOR AUTOMOTIVE SYSTEMS, the disclosure of which is incorporated herein by reference.

The navigation system 24 may store, retrieve, receive, and/or display various types of data including, for example and without limitation, weather/environmental data, road data including curvature, posted speed limits, and grade, as well as traffic data, as desired. The navigation system 24 may also be used to provide route instructions to a driver of the vehicle, and/or to provide a route for an autonomous drive controller to use. The navigation system 24 may include a global positioning system (GPS) device for determining and tracking position of the vehicle 10.

The batteries 14 are rechargeable by connection 16 to an off-vehicle charging station 40. Batteries 14 may also be recharged using an on-board charger (OBC) 42 that plugs into mains power 44. The controller 20 may communicate with the charging station 40, as desired, to allow, for example, the controller 20 to provide or receive control or data signals during charging operations. For example, the controller 20 may indicate battery type for batteries 14, or may provide a charging current control signal to the charging station 40, if desired, so that the charging station 40 provides an appropriate amount of charge current. The controller 20 may also provide battery temperature signals, or readiness signals for high current charging, to the charging station. The controller 20 may also control the OBC 42. Some examples further discussed below allow the controller 20 to manipulate charging current as part of a battery parameter characterization procedure.

Several examples that follow focus on the batteries 14 and associated systems. While these examples may be mostly used in the context of an electric vehicle lacking another source of power, the present innovation may also be used in hybrid vehicles having a second power source, such as an internal combustion engine 30, or a fuel cell or other power source onboard. As used herein, any such hybrid or all-electric vehicle is described as an electrified vehicle or “EV”. More pertinent than the choice of multiple power sources is the fact that the vehicle 10 includes one or more batteries 14 of size and capacity that will allow motive power to be generated by the electric motor 12. While a vehicle having wheels 46 is illustrated, it should also be understood that the present invention may be used in aviation as well as in fixed installations having rechargeable batteries 14 in which power losses and auxiliary power uses may be characterized.

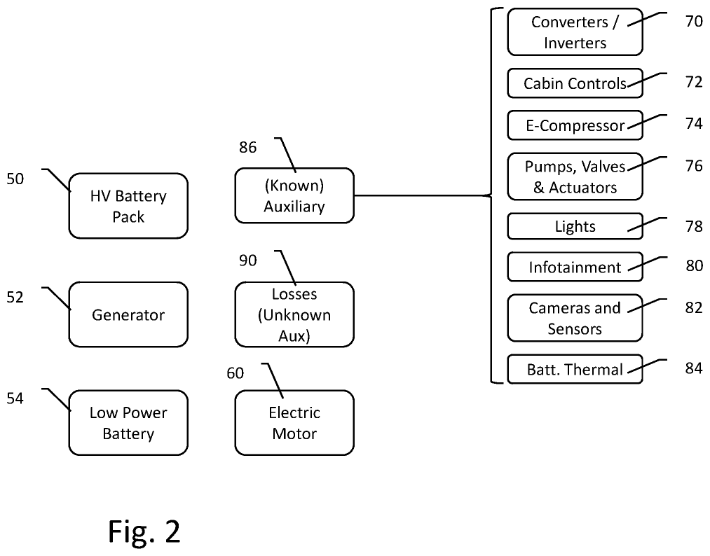

FIG. 2 illustrates electric power sources and power uses in an EV. The EV has a high voltage (HV) battery pack 50, which is the largest source of electric power. Many current EV implementations use lithium-based chemistry for the battery pack 50, though the present concepts are not limited to any particular battery chemistry. A generator 52 may be provided as well. For some vehicles, the generator 52 may be powered by regenerative braking and/or, for hybrid vehicles, by a separate fuel-cell or combustion engine. A low power battery 54 may also be present, and may take the form of, for example, an older technology lead acid battery.

The largest power consumer, typically, will be the MGU 60 when operating as an electric motor. Additional power may also be consumed by the transmission or other power train structures (differential, etc.) that are not shown. More than one electric motor 60 may be present in more than one MGU. The MGU may also be a power provider, for example, when an MGU is used to slow the vehicle (regenerative braking).

A large number of other power uses are also present, including internal converters and inverters 70 used, for example, to transfer power between the sources and one another as well as the major users. Cabin controls 72, including heating, cooling and/or ventilation use power, as does an electric compressor 74 which can be used in various ways, such as to support turbocharger function (for an internal combustion hybrid). Various electric pumps, valves and actuators are typically present in the vehicle, as indicated at 76, and may include systems for moving fluids about in the vehicle as well as transmission (gear-shifting) functions. Lights 78, cabin electronics or infotainment 80, and cameras and sensors 82 around the vehicle also use electric power. A battery thermal control system 84 may also be a consumer of power as the HV Battery pack typically includes a temperature control system to keep the battery pack operating in a desired temperature range. The various current and power consumers highlighted here are not intended to be exhaustive, limiting, or required for all instances; for example, not all the noted users may be present in every EV and there may be other systems that consume power as well (such as the transmission which may use power to determine, change and/or control gears). The HV Battery pack itself also consumes power due to internal impedance losses, as well as battery self-discharge, though this is not separately called out in the Figure.

These known or modeled auxiliary power uses (70, 72, 74, 76, 78, 80, 82, 84) are summed together and treated as known auxiliary power use 86. Each of these auxiliary power uses, for example, may be modeled off-line, or may be associated with a current consumption monitor, individually, in groups, or otherwise.

Losses 90 also consume power in various ways, and these are treated as the “unknown” auxiliary power, regardless of the actual source or location of such losses. As electric current is conveyed through wires, or converted between AC/DC, some power is lost to resistive heating. The battery cells in the HV battery pack have an internal current consumption which will reduce available capacity over time, and whenever current flows through a battery, some power is lost due to the battery internal resistance/impedance. Further, there may be additional losses in the system due to operation of various switches, fans, pumps, lights, etc. which may be outside of expected ranges, potentially indicating faults.

“Losses” at 90 does not encompass all possible power losses in the vehicle or system. Thus power losses that are downstream of electrical power consumption are omitted; that is, for example, friction losses when the vehicle tires slip relative to the roadway are not considered unless such losses would affect the difference between modeled and/or known electrical power consumed in the vehicle and the electrical power taken from the battery. Stated differently, the losses at 90 represent the difference between expected battery output power and actual battery output power. Better quantification of such losses 90 can be useful to enhance fault detection, predictive maintenance and predictive control processes, for example and without limitation.

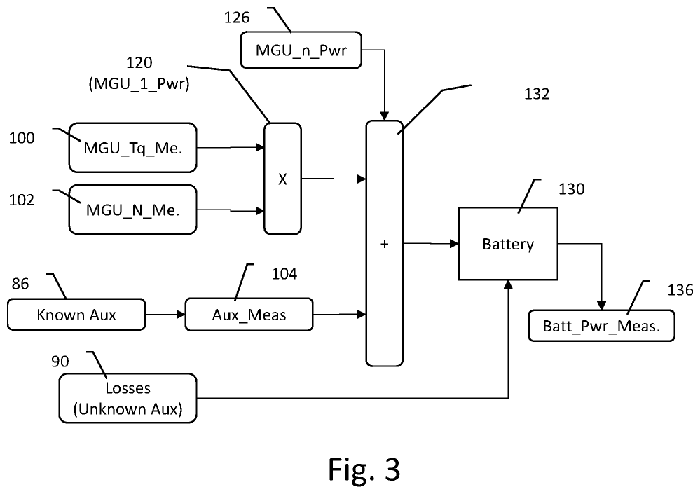

FIG. 3 illustrates a power and battery analysis model useful for an auxiliary power estimator. The illustration shows the processing of measured signals to determine both the actually consumed battery power as well as the demanded power of the battery. First, MGU power is calculated from the measured MGU torque 100 and measured MGU speed 102, as indicated at 120. If more than one MGU is present, one or more additional MGU powers can be summed, as indicated at 126. Known auxiliary power usage 86 (explained above in FIG. 2) is treated as measured auxiliary power consumption at 104. These known battery power demands are summed at 132. In addition, the unknown auxiliary losses 90 (again explained above relative to FIG. 2) also draw power from the battery 130.

The battery power usage at any given time is also measured at 136. For example a current monitor (coulomb counter) is provided at the battery pack output, and a battery pack voltage is measured as well. The battery current multiplied by the battery voltage gives the instantaneous battery power measurement 136. In the model, the losses 90 are characterizable in this following generalized formula:

$$Batt\_Pwr \_Meas = Total Batt\_Pwr \_Dem + Unknown Losses = Aux\_Meas + {\sum }_{∀ MGU} MGU\_n \_Pwr + Unknown\_Losses$$

Or using the reference numbers of FIG. 3:

$$Ref ( 136 ) = Ref ( 132 ) + Ref ( 90 )$$

However, such a general view does not give an accurate estimation of unknown auxiliary power (losses) as it may contain various offsets, lags, and dynamical errors that would be present in a dynamic system. In some illustrative examples, to better characterize these metrics, a Kalman filter approach is used.

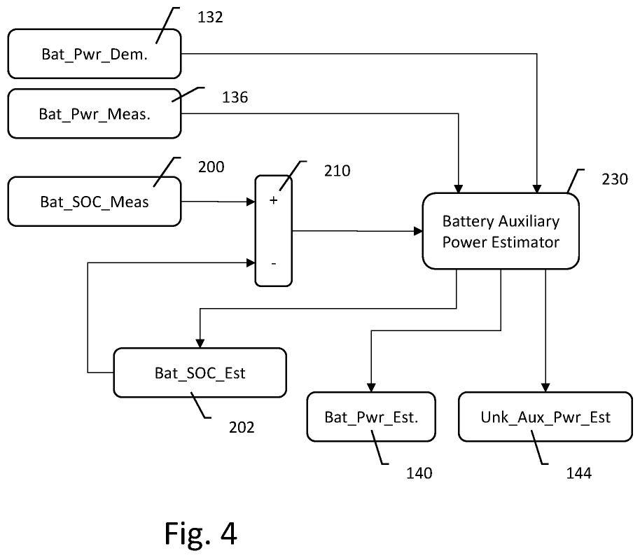

The Battery Auxiliary Power (BAP) Estimator, further detailed in FIG. 4, may be a controller or microcontroller, including an ECU, associated with a memory storing operational instructions in readable format, embodying a Kalman filter design. The Kalman filter design may take a suitable form, including any of an Unscented Kalman Filter, an Extended Kalman Filter, or an Iterated Extended Kalman Filter, for example and without limitation.

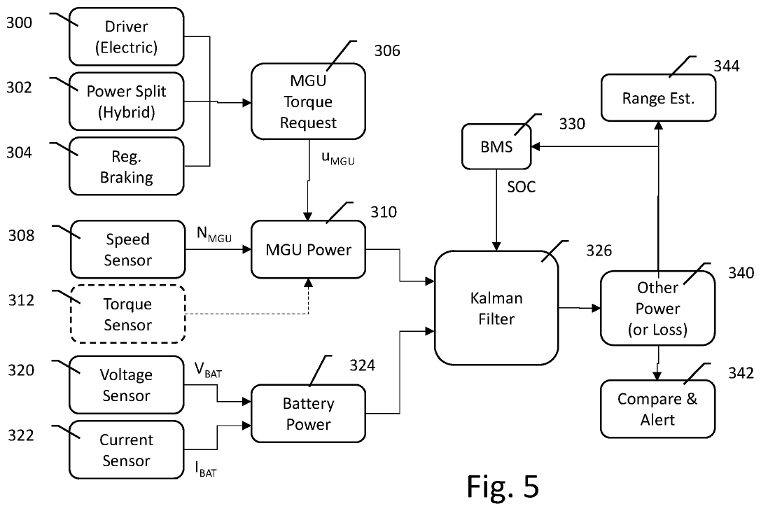

As shown in FIG. 4, the BAP Estimator 230 receives as inputs the known battery power demand 132, as well as the measured battery power 136. Each are received as a series of measurements or estimates. The BAP Estimator 230 also generates an estimated battery SOC 202 and receives a comparison of the estimate to a measured or estimated battery SOC 200. The estimated or measured battery SOC 200 may be derived in several different ways. The estimated or measured battery SOC 200 may be determined by the BAP Estimator 230 itself, or may be communicated to the BAP estimator 230 by the Battery Management System 330 (see FIG. 5). In one example, measured battery SOC 200 is determined by obtaining an at-rest battery open circuit voltage. In another example, measured battery SOC 200 may be determined over time by monitoring current flow into and out of the battery, subject to occasional correction when an at-rest open circuit battery voltage can be obtained (such as while the vehicle is parked and not charging). In another example, measured battery voltage, which may be corrected for battery current and internal resistance, is used to determine battery SOC by reference to a look a look-up table (which may incorporate changes due to aging).

The BAP Estimator 230 uses a Kalman filter design to smooth the noisy measurements and resulting analysis, and provides three separate outputs. First, an estimated battery output power at 140 is the smoothed version of signal 136, the measured battery current and voltage. The estimated battery power 140 may instead be a smoothed version of the battery power demand, signal 132, if desired, or both an estimated battery power and an estimated battery power demand may be output. Next, a battery SOC estimate 202 is generated. This estimate is compared at block 210 to the measured Battery SOC 202, with the difference provided as an input to the BAP Estimator 230. The error between measured Battery SOC 202 and estimated Battery SOC 210 can be used to determine unknown auxiliary battery power losses using the Kalman filter. Within the Kalman filter, the estimated Battery SOC 202 can be calculated as a function of battery output power (whether output or demand), previous battery SOC estimate, temperature, and other factors as desired.

The unknown auxiliary power estimate is also output, at 144. The Kalman filter in some examples treats the unknown auxiliary power estimate 144 as a system disturbance, without regard for any additional input data. This simplifies the model design, as the Kalman filter does not have to include variables to account for which auxiliary systems are operating at a given time. The data is smoothed by the Kalman filter so that, over time, the unknown auxiliary power estimate can be estimated in varying circumstances, allowing for mean unknown auxiliary power estimate and variance/deviation thereof to be determined. The unknown auxiliary power estimate may be, in some examples, generated by comparing changes in the difference between measured and estimated Battery SOC. In other examples, the unknown auxiliary power estimate may be generated by comparing the smoothed battery output signal 136 to the smoothed known battery demand signal 132. In some examples, both of these preceding methods are applied and data fusion is used to construct a single estimate from the battery SOC differences and the battery demand/output differences.

The BAP Estimate 230, in its Kalman filter implementation, does not need to handle auxiliary power system states in this example. Such states may, however, be tracked to yield a two or more auxiliary power thresholds. For example, in a given vehicle configuration, it may be known that certain auxiliary systems (battery thermal management, or cabin temperature controls, for example) may be more significant to auxiliary power usage than others (lighting, entertainment systems, etc.). Thus the experimental setup can be operated several times to determine the effect of certain systems being on or off. For example, during fast charging of the battery, the battery thermal management system may use more power than in other circumstances, thus an experimental run can be performed to determine estimated auxiliary power usage during fast charging of the battery. Likewise, operation of the cabin temperature controls (for example, air conditioning) may be set to different levels to obtain additional estimated power usage levels. These additional “granular experiments” may be optional.

Such granular additional elements may be accounted for by inclusion in the Battery Power Demand 132, which can be taken instead as the known battery demands in the system. The Battery Power Demand may then be considered as shown in this Equation:

$$Batt\_Pwr \_Dem = \sum Aux\_Known + {\sum }_{∀ {MGU}_{n}} MGU\_n \_Pwr$$

Using this formulation, block 132 can account for variation in the known auxiliary users, which may be measured values of power consumption or current draw, whether in lump form or not, or may rely on models of the auxiliary users. For example, it is common to include various power supplies that supply current to subsystems; monitoring power consumption or current from such power supplies may populate the summation of “Aux_Known” in the above formula, reducing the degree to which unknowns are actually present in the “Losses” factor and adding precision without complicating the Kalman filter. The system may further be configured to learn, using reference to subsystem states, power demands of the various subsystems when in each state (for example, a cabin air conditioner may have states of ON and OFF for the compressor of such a subsystem) may be extracted over time in a learning process, thus populating the Aux_Known elements of the above formula.

FIG. 5 shows in block form generation and use of an auxiliary power estimate. Here, an MGU Torque request is determined at 306, using suitable inputs such as the driver power request 300 (accelerator pedal of a purely electric vehicle, for example), the power split output 302 for a hybrid vehicle, and/or regenerative braking 304. It should be noted that the torque request 306 can be negative. The control signal, u_{MGU} is issued to the MGU (not shown), and also combined at block 310 with the output of the MGU Speed Sensor 308, which provides N_{MGU} to block 310. If desired, rather than the torque request, if a torque sensor 312 is provided, the MGU power at 310 may instead be calculated using the output of the torque sensor 312 and the speed sensor 308. The MGU power is provided to the Kalman Filter 326.

A voltage sensor 320 on the battery provides a voltage measurement, V_{BAT}, and a current sensor 322 on the battery provides a current measurement I_{BAT}. These are combined at block 324 to yield the output battery power, which is also provided to the Kalman filter. Operations in the Kalman filter may include consideration of the battery state of charge (SOC) which may be obtained from the Battery Management System (BMS) 330. The BMS 330 may be a separate controller adapted to manage the battery pack, including as a part thereof a battery thermal management system (BTMS) or at least communicating with a BTMS. The BMS 330 may be used to track battery usage, performance, and health measures, and may further control the thermal state of the battery using the BTMS for purposes of operating the battery during driving, managing the battery when parked, and tracking, managing and/or controlling battery charging as needed.

The battery power balance is given here:

$${P}_{bat} = {P}_{MGU} + {P}_{aux} = {P}_{MGU} + {P}_{aux , known} + {P}_{loss}$$

Where, P_{bat} is the measured battery power, P_{MGU} is the MGU power, Pₐᵤₓ, which is power consumed by auxiliary devices including losses. The Pₐᵤₓ term can be further broken into P_{aux,known}, which is the known auxiliary power used, and Pₗₒₛₛ, that is power drain due to losses throughout the system. If P_{MGU}>0, power is being consumed by the traction motor, and if P_{MGU}<0, power is being supplied by the generator.

The auxiliary power term, Pₐᵤₓ, is treated as the unknown, though as noted above, some components may be known or estimated. Thus:

$${P}_{aux} = {P}_{bat} - {P}_{MGU}$$

And therefore:

$${P}_{aux} = {U}_{bat} {I}_{bat} - {T}_{MGU} {ω}_{MGU}$$

### Where:

U_{bat} is the battery voltage measurement
I_{bat} is the battery current measurement
T_{MGU} is the MGU torque
W_{MGU} is the motor rotational speed in radians per second
   This estimation of the auxiliary power term is enhanced, in some examples, by the use of an internal model of the battery and the battery SOC, both of which may be tracked or maintained either on-vehicle or off-vehicle, such as in the cloud. Data for the internal model and battery SOC can be obtained from the BMS 330. The battery model can take any suitable form, and, in some examples, accounts for battery specific features such as aging, lithium plating, secondary electrolyte-interphase layer formation, electrolyte drying, dissolution of the positive electrode, loss of electrolyte, etc. Some examples may use a second order battery equivalent circuit model. Some examples may operate or use tools as described, for example, in U.S. patent application Ser. No. 18/520,155, filed Nov. 27, 2023, and titled EIS-BASED HEALTH DEGRADATION HANDLING FAST-CHARGING FOR ELECTRIC VEHICLES; this is merely one example and others may be used instead.

Battery SOC is generally tracked in any EV, for example by the BMS, and is often displayed to the driver as well. Some examples may track battery SOC using measurements of charge flow into and out of the battery cell, which can be updated as desired to account for loss of capacity in the battery. The battery SOC measurement may be subject to occasional correction when a battery voltage can be measured in low/zero current conditions, particularly if a rest interval precedes the measurement so that internal dynamics of the battery, which can affect battery open circuit voltage measurements, are steadied.

The Kalman filter can take several forms, including Extended, Unscented, etc. An illustrative example includes an Extended Kalman Filter (EKF), which uses an internal battery model, assuming the battery SOC is available, which can be represented in the state space as:

$$x ( t + 1 \vert t ) = f ( x ( t \vert t ) , u ( t ) ) + w ( t )$$

$$y ( t ) = g ( x ( t \vert t ) , u ( t ) ) + v ( t )$$

Where x is a vector of the internal battery model states, u is the battery power (expressed in Watts, if desired), y is the battery SOC in terms of a percentage of maximum SOC, f and g are functions that map battery power to battery SOC, and t is the discrete time instance. The functions f and g may be obtained from testing of the battery itself and can be evaluated using simulation. The functions f and g are also associated with process noise, w(t), and observation noise, v(t), each having zero mean and covariances Q and R, respectively. The battery power, u may also be a vector having multiple inputs, such as if multiple batteries are used or if a battery pack is treated analytically as more than one component.

The EKF can be characterized by these equations:

$$L = P ( t \vert t - 1 ) {{C}^{T} ( CP ( t \vert t - 1 ) {C}^{T} + R )}^{- 1}$$

$$C = \frac{dg ( x , u )}{dx}$$

$$A = \frac{df ( x , u )}{dx}$$

Where L is the observer feedback gain, C is the observation/output matrix, A is the state transition matrix, and P is the covariance estimate matrix. The functions f and g are again obtained from battery modeling. The battery model is then employed to design the state observer. The auxiliary power term, Pₐᵤₓ, is added to the internal battery power as an unknown additive disturbance signal. With the EKF, the data step is:

$$\hat{x} ( t \vert t ) = \hat{x} ( t \vert t - 1 ) + L ( y ( t ) - g ( \hat{x} ( t \vert t - 1 ) , u ( t ) )$$

$$P ( t \vert t ) = P ( t \vert t - 1 ) - L ( {CPC}^{T} + R ) {L}^{T}$$

And the EKF time step is:

$$\hat{x} ( t + 1 \vert t ) = f ( \hat{x} ( t \vert t ) , u ( t ) )$$

$$P ( t + 1 \vert t ) = AP ( t \vert t ) {A}^{T} + Q$$

Wherein \hat{x} is the internal estimator state based on the chosen battery model, u is the battery power, and y is a vector of the measured battery SOC and measured battery power. The observer uses the Kalman filter 326 to determine the MGU power, P_{MGU}, and the battery power, P_{bat}.

This resultant term, auxiliary power 340, can be used in several ways around the system. Simulations and experiments suggest that the auxiliary power Pₐᵤₓ may typically stay in a range between 1-2 kilowatts in certain vehicles. Comparison, as indicated at 342, to a threshold, such as 2 kW (or higher or lower, and/or calibrated to a particular vehicle) can be used to identify internal problems or faults, such as issues within the MGU, or in any of the auxiliary systems, any of which could result in excess power/current draw and which could be captured by this approach to calculating auxiliary power. If the threshold is exceeded, an alert may be generated at 342, or an error code may be recorded for future use in vehicle diagnostics or service.

The auxiliary power threshold may be calibratable. Multiple thresholds can be used, depending, for example, on system state, such as whether the battery is being charged (which would use higher auxiliary power for the battery thermal management system) or cabin controls are using the air conditioning (also relatively higher power). Industrial vehicle auxiliary systems may take larger power, and so the comparison term may be variable or larger than just described. For example, if electric power is used for a pump enabling hydraulic systems, a hoist for a dump truck, a system that spins the barrel of a concrete truck, or a refrigeration unit for a refrigerated truck, a separate or different threshold may be used when such auxiliary power systems are in use.

Knowledge of the auxiliary power usage can also be integrated in vehicle range determinations 344, where the vehicle range may vary. While the absolute impact of auxiliary power usage to vehicle range for a passenger vehicle will be relatively low, such data can help avoid unnecessary error determinations and provide stability and certainty to the range calculation. Auxiliary power usage 340 may also be reported to the BMS, to help ensure that the modelling on the BMS can remain accurate, as needed.

The auxiliary power can also be communicated to a power split calculation at 302. Auxiliary power will generally be a current draw on the battery, and so would be a useful input to the power split analysis. The power split analysis, for a hybrid vehicle, determines how much power to obtain from the battery pack versus the fuel cell or combustion engine at a given time. A predictive power split will additionally look ahead, including for example, at predicted driving demands (possibly based on road type, speed limits, turns, slopes, driver behavior and/or traffic and traffic controls); auxiliary power may be added to such analysis as well so that battery current draw will be accurately predicted or otherwise characterized.

In some examples, features of some vehicles may be treated as state-specific known auxiliary users, where a modeled, measured, or learned estimate of power consumption for the auxiliary user may be used to reduce the size of the unknown auxiliary power consumption in the preceding formulations. The EKF may be adjusted to use this formulation instead:

$${P}_{aux \_ unknown} = {P}_{bat} - ( {P}_{MGU} + {P}_{aux \_ known} )$$

In this reformulation of the Kalman filter, the known auxiliary power usage P_{aux_known}, which includes those auxiliary power users for which measured, estimated, or modeled consumption are known, are separated from the unknown users and losses. The known auxiliary power usage may include any auxiliary power user outside of the MGU that can be estimated/modeled/measured, including battery thermal controls, cabin controls (vehicle air conditioning for example), vehicle-specific users (hydraulic or air compressor use), etc. Other aspects of the Kalman filter design may be adjusted or may remain the same. In some examples, known auxiliary uses can be summed with MGU power use.

The blocks shown in FIG. 5 can be manifested in various forms. The blocks at 300, 302, 304 may represent signals generated by, for example, the driver interface (pedal controls for example) for block 300, by an electronic control unit (ECU) which typically would be a microcontroller or microprocessor accompanied by any suitable specialized circuitry (ASICs, logic, and digital or analog circuitry), as well as memory for storing machine readable instructions for the power split at 302, as well as braking signals, or speed/velocity change demands from a driver interface and/or other control system including emergency override and/or autonomous drive controller, at 304. The MGU torque request 306 sums these signals and may be another microcontroller and associated memory, or may be a callable function with a stored software instruction set.

The sensors 308, 312, 320, 322 may take conventional and known forms for such mechanical devices. The MGU power block 310 and battery power block 324 may each be a separate microcontroller but are more likely implemented as part of the software instruction set executed in the system controller for calculating power to be provided to the Kalman Filter 326, which will in turn be a software block callable by a system controller. The battery power block 324 may instead be part of the battery management system 30, if desired. The Kalman Filter 326 may be provided as part of a specialized hierarchical controller, or may simply be managed (such as by providing initial parameters) from a hierarchical controller, including using those as shown in U.S. patent application Ser. No. 17/241,668, filed Apr. 27, 2021 and titled ADVANCED CONTROL FRAMEWORK FOR AUTOMOTIVE SYSTEMS, the disclosure of which is incorporated herein by reference. BMS 330 may be a separate controller and with associated memory and stored instruction code, as well as any suitable analog or digital circuitry. The output AUX power signal 340 and range estimate 344 are generated by the controller software. The comparison and alert block 342 may represent or be executed by the controller, but also provides signals used, for example, to communicate (via communications circuitry) to an off-vehicle server, for reporting to a fleet database or controller for example, as well as to control a driver interface that is used to provide a suitable alert calling for service.

The alert at 342 may also cause storage of a diagnostic trouble code (DTC) alert. Such DTCs can later be retrieved during a service visit. A trained technician, with or without additional digital tools, can then use the DTC for further troubleshooting.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein. In the event of inconsistent usages between this document and any documents so incorporated by reference, the usage in this document controls. The terms “a” or “an” are used, as is common in patent documents, to include one or more than one, independent of any other instances or usages of“at least one” or “one or more.” Moreover, in the claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic or optical disks, magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, innovative subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the protection should be determined with reference to the appended claims, along with the full scope of equivalents to which such claims are entitled.

What is claimed is:

1. A method of estimating power losses in a vehicle having a motor-generator-unit (MGU) used by the vehicle to provide motive power, the method comprising:
calculating or measuring torque of the MGU:
calculating or measuring speed of the MGU;
using the MGU torque and MGU speed to determine MGU power;
measuring current output of a battery pack of the vehicle;
measuring voltage of the battery pack of the vehicle;
using the measured current and measured voltage to determine battery pack output power;
applying the MGU power and battery pack power as inputs to a Kalman filter;
treating the power losses as an unknown disturbance in the Kalman filter; and
obtaining an estimate of the power losses from the Kalman filter.

2. The method of claim 1, wherein the estimate of power losses includes power used by auxiliary systems of the vehicle as well as power losses in the MGU.

3. The method of claim 1, further comprising estimating or measuring known auxiliary power uses in the vehicle, and applying the known auxiliary power uses as an input to the Kalman filter, wherein the estimate of power losses from the Kalman filter omits the known auxiliary power uses.

4. The method of claim 1, wherein the speed of the MGU is measured by a speed sensor.

5. The method of claim 1, wherein the torque of the MGU is calculated from an MGU power request.

6. The method of claim 1, further comprising comparing the estimated power losses to a threshold, finding that the estimated power losses exceed the threshold, and generating an alert in response to the estimated power losses exceeding the threshold.

7. The method of claim 1, further comprising correcting a range estimate for the vehicle using the estimated power losses, and reporting the corrected range estimate to a driver of the vehicle.

8. The method of claim 1, wherein the Kalman filter is an Unscented Kalman Filter, an Extended Kalman Filter, or an Iterated Extended Kalman Filter.

9. A configurable controller for a vehicle having a motor-generator-unit (MGU) used by the vehicle to provide motive power, the configurable controller programmed to perform a method of estimating power losses in the vehicle by:
calculating or measuring torque of the MGU:
calculating or measuring speed of the MGU;
using the MGU torque and MGU speed to determine MGU power;
measuring current output of a battery pack of the vehicle;
measuring voltage of the battery pack of the vehicle;
using the measured current and measured voltage to determine battery pack output power;
applying the MGU power and battery pack power as inputs to a Kalman filter;
treating the power losses as an unknown disturbance in the Kalman filter; and
obtaining an estimate of the power losses from the Kalman filter.

10. The configurable controller of claim 9, the estimate of power losses includes power used by auxiliary systems of the vehicle as well as power losses in the MGU.

11. The configurable controller of claim 9, further programmed for estimating or measuring known auxiliary power uses in the vehicle, and applying the known auxiliary power uses as an input to the Kalman filter, wherein the estimate of power losses from the Kalman filter omits the known auxiliary power uses.

12. The configurable controller of claim 9, wherein the speed of the MGU is measured by a speed sensor.

13. The configurable controller of claim 9, wherein the torque of the MGU is calculated from an MGU power request.

14. The configurable controller of claim 9, further programmed for comparing the estimated power losses to a threshold, finding that the estimated power losses exceed the threshold, and generating an alert in response to the estimated power losses exceeding the threshold.

15. The configurable controller of claim 9, further programmed for correcting a range estimate for the vehicle using the estimated power losses, and reporting the corrected range estimate to a driver of the vehicle.

16. The configurable controller of claim 9, wherein the Kalman filter is an Unscented Kalman Filter, an Extended Kalman Filter, or an Iterated Extended Kalman Filter.

17. A vehicle having a motor-generator unit and a configurable controller as in claim 9.

18. The vehicle of claim 17, wherein the vehicle is a purely electric vehicle.

19. The vehicle of claim 17, wherein the vehicle is a hybrid vehicle having, in addition to the MGU, a fuel cell or a combustion engine for providing motive power.
